(19) United States
(12) Patent Application Publication
(10) Pub. No.: US 2013/0181197 A1
(43) Pub. Date: Jul. 18, 2013

(54) ORGANIC ELECTROLUMINESCENT DEVICES

(71) Applicant: Electronics and Telecommunications Research Institute, Daejeon (KR)

(72) Inventors: Jeong Ik LEE, Gyeonggi-do (KR); Chul Woong Joo, Seoul (KR); Jin Woo Huh, Daejeon (KR); Nam Sung Cho, Daejeon (KR); Joo Hyun Hwang, Seoul (KR); Jaehyun Moon, Daejeon (KR); Jun-Han Han, Daejeon (KR); Jin Wook Shin, Incheon (KR); Seung Koo Park, Daejeon (KR); Doo-hee Cho, Daejeon (KR); Hye Yong Chu, Daejeon (KR)

(73) Assignee: Electronics and Telecommunications Research Institute, Daejeon (KR)

(21) Appl. No.: 13/733,956

(22) Filed: Jan. 4, 2013

(30) Foreign Application Priority Data
Jan. 18, 2012 (KR) 10-2012-0005616

(51) Int. Cl. H01L 33/60

(52) U.S. Cl. CPC H01L 33/60
USPC 257/40

(57) ABSTRACT

Organic electroluminescent devices are provided. The organic electroluminescent device may includes a first light emitting part including a transparent first electrode, a first organic light emitting layer, and a transparent second electrode which are stacked, and a capping layer stacked on the first light emitting part. The first light emitting part emits light of a first wavelength, and the capping layer reflects the light of the first wavelength and transmits light of a second wavelength. Thus, the lights of the first and second wavelengths are emitted in high efficiency.

### CROSS-REFERENCE TO RELATED APPLICATIONS

This U.S. non-provisional patent application claims priority under 35 U.S.C. §119 to Korean Patent Application No. 10-2012-0005616, filed on Jan. 18, 2012, the entirety of which is incorporated by reference herein.

### BACKGROUND

The inventive concept relates to organic electroluminescent devices and, more particularly, to organic electroluminescent devices capable of changing a color with high light extraction efficiency.

An organic light emitting diode being an example of organic electroluminescent devices may include an anode, a cathode, and an organic light emitting layer disposed the anode and the cathode. Holes supplied from the anode may be combined with electrons supplied from the cathode in the organic light emitting layer to form excitons, and then the excitons may be recombined to emit light. The organic light emitting diode may be a self-illuminated device. The organic light emitting diode has been developed to be applied to display devices because of a wide viewing angle, high response speed, and high color reproduction range thereof. Additionally, various researches have been conducted for applying the organic light emitting diode to the lighting industry.

FIG. 1 is a schematic view illustrating a stack structure of a conventional organic electroluminescent device. In FIG. 1, a conventional organic light emitting diode includes a substrate 10, an anode 20 being a transparent electrode, an organic light emitting layer 30 being a reflecting electrode 40, and a passivation layer 50 which are sequentially stacked.

The organic light emitting diode may generate light having one of a red (R) color, a green (G) color, and a blue (B) color. Alternatively, the organic light emitting diode may generate white light. A plurality of organic light emitting diodes emitting lights of different wavelengths from each other may be combined with each other for showing a desired color.

Korean Laid Open Patent Application No. 2007-0008071 proposes stacked organic light emitting structures of which widths are equal to each other. In the reference, a planar area of RGB sub-pixels having the stacked organic light emitting structures may be equal to a planar area of a pixel, such that brightness may increase and pixels may become highly fine. However, light generated from a middle sub-pixel of the stacked sub-pixels may be reflected by a lower sub-pixel and/or an upper sub-pixel and then be radiated outside the pixel. Thus, light efficiency may be reduced.

### SUMMARY

Embodiments of the inventive concept may provide organic electroluminescent devices capable of varying a color with high light extraction efficiency.

In one aspect, an organic electroluminescent device may include: a first light emitting part including a transparent first electrode, a first organic light emitting layer, and a transparent second electrode which are stacked, the first light emitting part emitting light of a first wavelength; and a capping layer stacked on the first light emitting part, the capping layer reflecting the light of the first wavelength and transmitting light of a second wavelength.

In another aspect, an organic electroluminescent device may include: a first light emitting part including a transparent first electrode, a first organic light emitting layer, and a transparent second electrode which are stacked, the first light emitting part emitting light of a first wavelength; a second light emitting part including a transparent third electrode, a second organic light emitting layer, and a reflective fourth electrode which are stacked, the second light emitting part emitting light of a second wavelength; and a capping layer disposed between the first organic light emitting layer and the second organic light emitting layer, the capping layer reflecting the light of the first wavelength and transmitting the light of the second wavelength.

In some embodiments, the capping layer may be stacked on the second electrode. Here, the first electrode may be an anode and the second electrode may be a cathode.

In other embodiments, the first electrode, the first organic light emitting layer, the second electrode, and the capping layer may be sequentially stacked on a transparent substrate.

In still other embodiments, the capping layer may partially reflect the light of the first wavelength and may partially transmit the light of the second wavelength.

In even other embodiments, the organic electroluminescent device may further include: a micro-resonator of the second wavelength disposed between the first light emitting part and the second light emitting part.

### BRIEF DESCRIPTION OF THE DRAWINGS

The inventive concept will become more apparent in view of the attached drawings and accompanying detailed description.

FIG. 1 is a schematic view illustrating a conventional organic electroluminescent device;

FIG. 2 a schematic view illustrating an organic electroluminescent device according to embodiments of the inventive concept;

FIG. 3 is a schematic view illustrating a structure of a phosphorescence white organic electroluminescent device having a double-layered light emitting layer;

FIG. 4 is a schematic view illustrating a method of operating a triplet harvesting type hybrid white organic electroluminescent device;

FIG. 5 is a schematic view illustrating a structure of a direct recombination type hybrid white organic electroluminescent device;

FIG. 6 is a schematic view illustrating a light extracting principle of a micro lens array;

FIG. 7 is a schematic view illustrating a micro-resonance principle using a Bragg minor;

FIG. 8 is a schematic view illustrating an organic electroluminescent device according to some embodiments of the inventive concept;

FIG. 9 is a schematic view illustrating an organic electroluminescent device according to other embodiments of the inventive concept; and

FIG. 10 is a graph illustrating light transmittance and light reflectance of a capping layer.

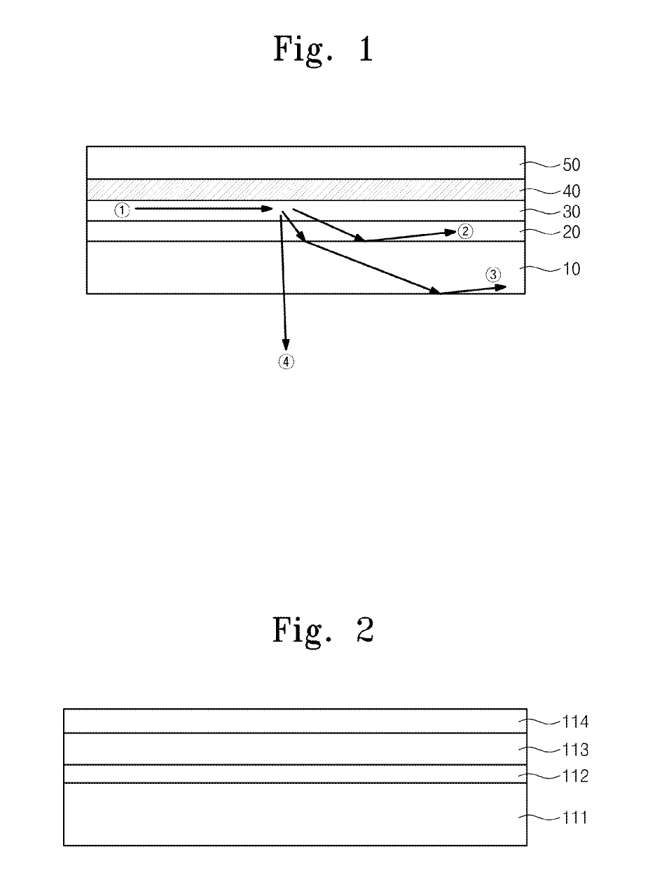

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

FIG. 2 is a schematic view illustrating an organic electroluminescent device according to embodiments of the inventive concept.

An organic electroluminescent device (e.g., organic light emitting diode (OLED)) illustrated in FIG. 2 may include a substrate 111, a first electrode 112, an organic light emitting layer 113, and a second electrode 114 which are sequentially stacked.

The substrate 111 may provide a physical hardness of the organic electroluminescent device and may function as a transparent window. The substrate 111 may be formed of a transparent glass or a transparent plastic. The transparent plastic may include at least one of polyethylene terephthalate (PET), polycarbonate (PC), polyethersulfone (PES), and polyimide (PI).

The first electrode 112 may be an anode or a cathode. For the purpose of ease and convenience in explanation, the first electrode 112 is defined as the anode and a transparent electrode formed of ITO hereinafter.

The second electrode 114 may have polarity opposite to that of the first electrode 112. For example, if the first electrode 112 is the anode, the second electrode 114 is the cathode. Alternatively, if the first electrode 112 is the cathode, the second electrode 114 is the anode.

The organic light emitting layer 113 generates light by a power provided from the first and second electrodes 112 and 114. The organic light emitting layer 113 includes an organic material. For example, when an electric field is applied to the organic electroluminescent device, electrons and holes may be recombined with each other in the organic light emitting layer 113 to release energy. Thus, light of a specific wavelength is generated. In other words, the organic electroluminescent device may be a self-illuminated device using the above principle. The organic electroluminescent device may include the anode 112 (e.g., an ITO layer), a hole injecting layer, a hole transport layer, a light emitting layer, an electron transport layer, an electron injecting layer, and the cathode 114 (e.g., a metal electrode) which are sequentially stacked on the substrate 111. Here, the layers between the both electrodes 112 and 114 are defined as the organic light emitting layer 113. For example, the organic light emitting layer 113 may include the hole injecting layer, the hole transport layer, the light emitting layer, the electron transport layer, and the electron injecting layer which are disposed between the first and second electrodes 112 and 114.

The organic light emitting layer 113 may be an important element of a light source for lightning. The organic light emitting layer 113 may have one of a stack structure, a single light emitting layer structure, a horizontal RGB structure, and a down conversion structure according to a device structure. Generally, the organic light emitting layer 113 may have the stack structure capable of being easily manufactured and obtaining high efficiency. Additionally, the organic electroluminescent device may be categorized as any one of a fluorescence white organic electroluminescent device, a phosphorescence white organic electroluminescent device, and a hybrid white organic electroluminescent device according to a kind of a material used therein. If the organic electroluminescent device uses a fluorescent material, stability of the organic electroluminescent device may be excellent but it is difficult to obtain high efficiency of the organic electroluminescent device. If the organic electroluminescent device uses the phosphorescent material, the high efficiency of the organic electroluminescent device may be obtained but it is difficult to obtain a stable blue material. In order that the problems of the above materials complement each other, he blue color may use the fluorescent material and other colors may use the phosphorescent materials.

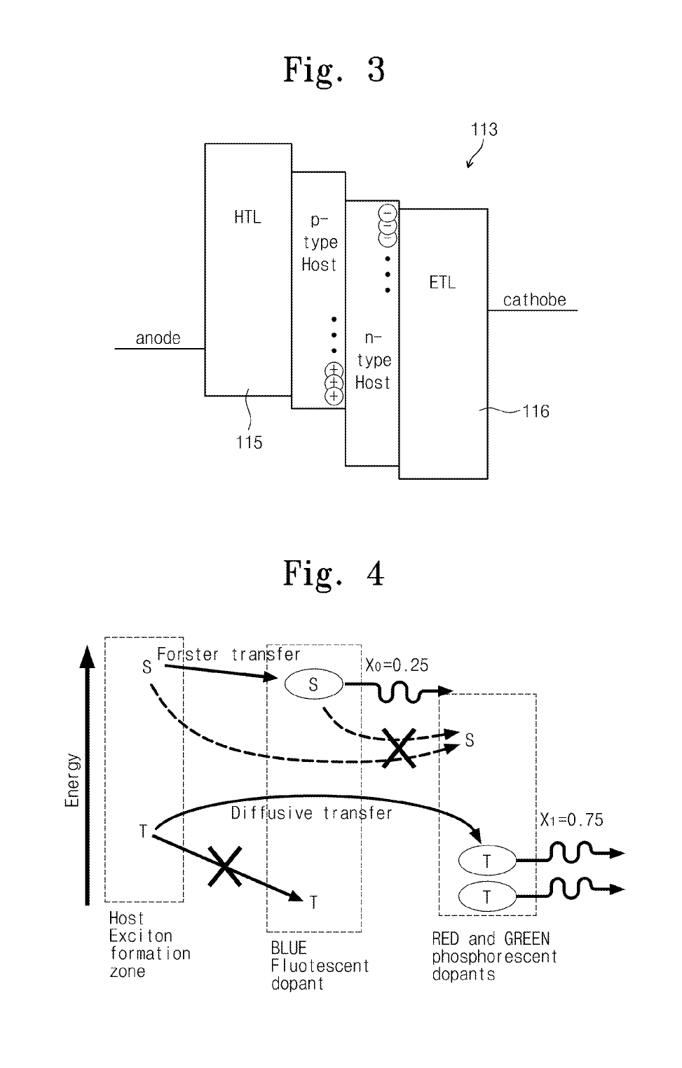

The phosphorescent device may include a hole injecting/transport layer 115, an electron injecting/transport layer 116, and a double-layered light emitting layer 113 as illustrated in FIG. 3 which shows a structure of a phosphorescence white organic electroluminescent device having a double-layered light emitting layer. The double-layered light emitting layer 113 may include a p-type host and an n-type host. Each of the hosts has a HOMO/LUMO structure having a high hole/electron injecting barrier. The structure of the double-layered light emitting layer 113 may be similar to a PN junction of a light emitting diode. A recombination zone may be limited to an interface region between the two hosts in the double-layered light emitting layer 113, such that it is possible to minimize a current loss. The materials of the double-layered light emitting layer 113 may require electro-chemical/thermal stability, triplet energy higher than that of a blue phosphorescent dopant, and high hole or electron mobility. Here, if a hole transport layer material or an electron transport layer material having high charge mobility and a triplet energy higher than that of the blue phosphorescent dopant exists, it is possible to provide high-degree of freedom in a design of the device structure.

The development of a new material having wide triplet energy for the hosts may be an important point for developing the phosphorescent organic light electroluminescent device. Additionally, the hole transport layer and the electron transport layer may also have to wide triplet energy in order that the charge mobility and the stability are maintained and the triplet energy of the blue phosphorescent dopant does not disappear. Furthermore, it is important to reduce the number of dopants. The dopants for a display device may have a narrow spectrum for securing a wide color reproduction range. Alternatively, the dopant for lighting may have a wide spectrum for securing a high color rendering index with few dopants. Thus, the material of the organic electroluminescent device for the display device may have to be developed independently from the development of the material of the organic electroluminescent device for the lighting.

Meanwhile, the blue color phosphorescent material having a stability problem is replaced with a fluorescent material in the phosphorescent white organic electroluminescent device described above, thereby forming the hybrid white organic electroluminescent device. The hybrid white organic electroluminescent device may be categorized as one of a triplet harvesting type capable of using a triplet of a fluorescent layer and a direct recombination type not capable of using the triplet of the fluorescent layer.

The triplet harvesting type may change an entire current into light energy in theory, such that it is very attractive. In other words, the triplet harvesting type organic electroluminescent device may obtain the same efficiency as the phosphorescent white organic electroluminescent device and secure the device stability, such that researchers are concerned about it. FIG. 4 shows a method of operating the triplet harvesting type hybrid white organic electroluminescent device. As illustrated in FIG. 4, electrons and holes may be mostly recombined with each other in the fluorescent layer constituting the light emitting layer, so that blue light is generated by singlet excitons of the fluorescent layer. The triplets not used in the recombination zone of the fluorescent layer may be moved into the phosphorescent layer by diffusive transfer to generate green and red phosphorescent lights. By the described principle, the singlet excitons of 25% may be converted into the blue light in the fluorescent layer and the triplet excitons of 75% may be converted into the green light and the red light in the phosphorescent layer. Thus, a converting efficiency of 100% may be obtained.

In the above device, it is important to confine the recombination zone in only the fluorescent layer and to control the diffusive transfer for using the triplet excitons in only the phosphorescent layer. However, it may be difficult to use the above type hybrid device due to the above particular operating method. In other words, the triplet excitons of the fluorescent layer may have to be moved into the phosphorescent layer without loss. However, the triplet excitons may be lost in the fluorescent layer by a non-light emitting process or be moved from the phosphorescent layer to the fluorescent layer again to be lost. Here, information for a desired path through which the triplet excitons fast passes may lack, such that it may be difficult to design the device.

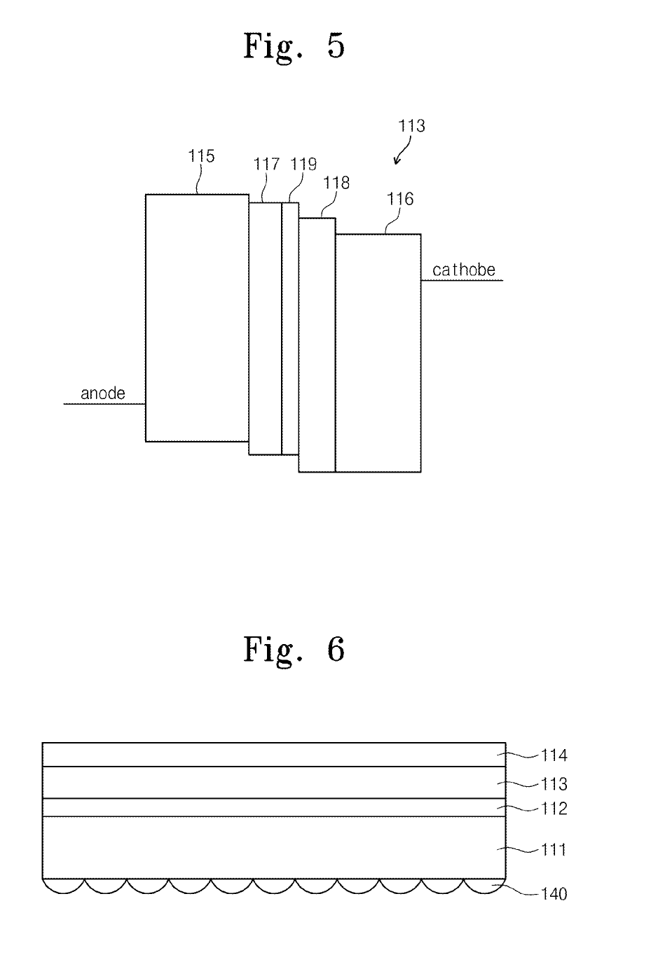

As illustrated in FIG. 5, in the direct recombination type hybrid white organic electroluminescent device, a recombination zone may be formed all of the fluorescent layer 118 and the phosphorescent layer 117. Thus, light may be omitted from all of the fluorescent and phosphorescent layers 118 and 117. Differently from the above triplet harvesting type, the direct recombination type may not use the triplet excitons of a blue fluorescent layer, such that the efficiency thereof may be low. However, the direct recombination type hybrid white organic electroluminescent device may use various materials and have high-degree of freedom in design thereof. An interlayer 119 separating the fluorescent layer 118 from the phosphorescent layer 117 may play an important part in the direct combination type hybrid white organic electroluminescent device. The interlayer 119 may control the formation of the recombination zone through the fluorescent layer 118 and the phosphorescent layer 117. Additionally, the interlayer 119 may prevent the triplet excitons of the phosphorescent layer 117 from being moved into the fluorescent layer 118.

Another problem of the organic electroluminescent device described above may be a light extraction problem.

As described above, the materials used in the light emitting layer may include the fluorescent material and the phosphorescent material. Since the phosphorescent organic electroluminescent device uses all of the excitons formed by recombination for emitting light, theoretical inner quantum efficiency thereof may be about 100%. Thus, the phosphorescent organic electroluminescent device may have the excellent theoretical inner quantum efficiency which is four times greater than that of the fluorescent organic electroluminescent device. But a lifetime of the phosphorescent organic electroluminescent device may be short. Recently, the phosphorescent materials are lively developed to improve the lifetime as well as the inner quantum efficiency of the phosphorescent organic electroluminescent device. However, even though the inner quantum efficiency of the organic electroluminescent device is 100%, 20% of the intensity of the emitting light may be outputted outside the organic electroluminescent device, and 80% of the intensity of the emitting light may be lost by wave-guiding effect caused by difference between refractive indexes of the substrate 111, the first electrode 112, and the organic light emitting layer 113 and total reflection effect caused by difference between refractive indexes of the substrate 111 and air.

A refractive index of the organic light emitting layer 113 may have a range of about 1.6 to about 1.9, and a refractive index of the ITO generally used as the anode may have a range of about 1.9 to about 2.0. A thickness of the organic light emitting layer 113 and the anode may have a range about 100 nm to about 400 nm. The glass widely used in the substrate 111 may have a refractive index of about 1.5. Thus, a planar waveguide may be freely formed in the organic electroluminescent device. A rate of light lost in an inner guided mode by the above problems may be about 45%. Additionally, since the refractive index of the substrate 111 is about 1.5 and a refractive index of external air is 1, incident light of a critical angle or more may be total-reflected to be isolated in the inside of the substrate 111 when light is outputted from the substrate 111 to the outside thereof. A rate of the isolated light may be about 35%, such that the emitting light of only about 20% may be outputted to the outside of the organic electroluminescent device.

Due to the low light extraction efficiency, the outer light efficiency of the organic electroluminescent device may be low, such that a light extraction technique may be an important technique for improving efficiency, brightness, and lifetime of the organic electroluminescent device.

An internal light extraction may mean a technique extracting the light isolated in the organic light emitting layer/ITO layer by the difference between the anode and the substrate to the outside of the organic electroluminescent device. An external light extraction may mean the light isolated in the substrate to the outside (e.g., air) of the organic electroluminescent device.

The external light extraction may limitedly improve light efficiency by 1.6 times. The external light extraction may require minimizing color variation caused by a diffraction phenomenon. The external light extraction technique may form a micro lens array, an external light scattering layer, and/or an anti-reflective film.

The internal light extraction technique may theoretically improve external light efficiency by three or more times. However, the internal light extraction technique may sensitively influence an internal interface in the organic electroluminescent device, such that electrical, mechanical, and chemical properties as well as the optical effect must be satisfied. An internal light scattering layer, surface modification of the substrate, a refractive index controlling layer, a photonic crystal, and/or a nano-structure may be used for the internal light extraction technique.

The micro lens array of the external light extraction may include small lenses which have a diameter less than 1 mm and be two-dimensionally arranged on a surface of the substrate facing the air. As illustrated in FIG. 6, the micro lens 140 of the micro lens array has a curved surface. Thus, an incident angle of light with respect to a surface tangent line of the micro lens 140 is smaller than the critical angle, so that the light is not total-reflected. As a result, the light is not confined in the substrate 111 and is extracted to the outside of the organic electroluminescent device. The micro lens array may be formed of a material having the same refractive index as the substrate 111. A diameter of the micro lens 140 may be several tens μm. As a density of micro lens 140 increases, light extraction efficiency may increase. Light distribution may be varied depending on a shape of the micro lens 140. The external light extraction structure using the micro lens array may be bonded to the substrate 111 to increase efficiency by about 50%.

The external light scattering layer in the external light extraction may be formed to have a sheet-shape and then be bonded to the substrate similarly to the micro lens array. Alternatively, a solution for the external light scattering layer may be coated on the substrate and then be hardened to form the external light scattering layer. The external light scattering layer may not cause color variation according to a view angle and an interference color. The light distribution of the light passing through the external light scattering layer may maintain Lambertian distribution. The external light scattering layer may have a good structure applied to a white OLED lighting panel. However, if the external light scattering layer becomes thicker and light scattering particles are formed to have a multi-layered structure, a scattering effect of light having a short wavelength may be greater than that of light having a long wavelength, so that transmitted light may have a yellowish red color. A refractive index, a size, and a density of scattering particles and a refractive index and absorption spectrum of the material should be controlled for minimizing spectrum variation caused by the scatting effect difference according to the wavelength of light. In an external fluorescent colloid structure, a ratio of absorbed light and scattered re-emitted light may be sensitively varied depending on a thickness, a size, a concentration of the fluorescent material. Thus, the external fluorescent colloid structure may be carefully designed. It may be effective that the external light scatting layer may be formed using a polymer sheet containing small air bubbles. Difference between the refractive index (i.e., 1.0) of the air bubble and the refractive index (e.g., about 1.5) of the material may be great, so that light scattering effect may greatly occur. Thus, the thickness of the external light scattering layer may be reduced and spectrum variation may be minimized

Then anti-reflective film of the external light extraction may be formed a section of an optical device for preventing light reflection caused by sudden refractive index variation at the section of the optical device and for increasing the amount of transmitted light. The anti-reflective film may include one, two, or three layers. When light is incident to and transmitted through a glass substrate, the light may be reflected twice, such that light of 8% may be lost by the reflection. However, the light may be reflected once in the organic electroluminescent device due to the structure thereof when the light is outputted to the external air. Thus, the light extraction efficiency of about 4% may increase if the anti-reflective film is used for the external light extraction. In order that reflection of vertically incident light of a single wavelength is minimized, a material having a refractive index equal to the square root of a refractive index of the substrate may be deposited on the substrate with a thickness equal to a quarter of the single wavelength. However, several layers having different materials from each other should be deposited on the substrate in order that reflecting rates of lights of several wavelengths such as a visible ray region are minimized

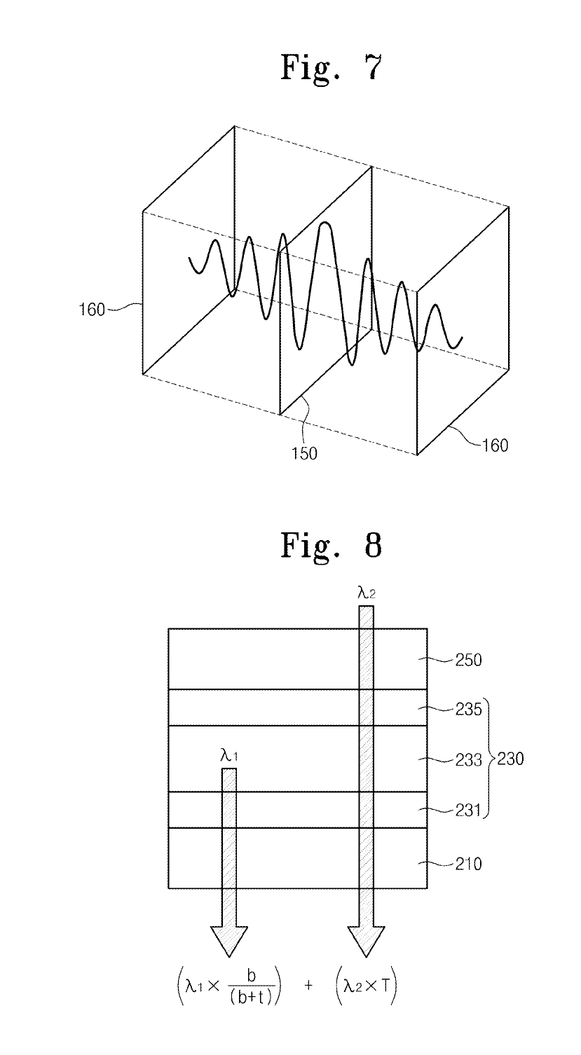

A micro-resonance of the internal light extraction is called ‘micro cavity’. As illustrated in FIG. 7, the micro-resonance may be caused by two Bragg mirrors 160 (or two metal mirrors) and a spacer layer 150 disposed between the two Bragg minors 160.

A thickness of the spacer layer 150 may be substantially equal to a wavelength for generating a standing wave of a visible ray. Thus, resonance of the internal light extraction is called as the micro-resonance. In the organic electroluminescent device, the micro-resonance may include a strong cavity and a weak cavity. The organic electroluminescent device may have the weak cavity without a specific design for a resonance structure. In other words, since the organic electroluminescent device includes the ITO anode having the refractive index of about 1.9, the metal cathode having the refractive index of about 1.9, and the organic light emitting layer disposed between the ITO anode and the metal cathode. The light emitting layer has the refractive index within a range of about 1.6 to 1.9 and the thickness of several hundreds nm. Thus, the organic electroluminescent device may naturally have the micro-resonance structure. As a result, the light extraction efficiency may be greatly changed depending on the thickness of the organic light emitting layer and the thickness of the ITO anode. Particularly, a ratio of the light extraction mode to the internal/external guided mode may be changed from about 22% to about 55% as a relative position of the recombination zone is changed.

Additionally, if a thickness of the cathode is greater than λ/4 where the λ is a wavelength of light, the light extraction efficiency may be reduced. Thus, the thickness of the cathode may be equal to or less than λ/4.

A tandem structure using a multi-layered organic light emitting layer may use various micro-resonance structures, so as to be used in a method of manufacturing a color modulation OLED panel. For forming the micro-resonance structure, a Bragg mirror layer may be deposited before the layers of the organic electroluminescent devices are deposited, and thicknesses of the layers of the organic electroluminescent device may be controlled. Thus, surface defects may not be caused by the micro-resonance structure, such that the micro-resonance structure may be easily applied to mass production of the panels. However, it may be difficult to use the micro-resonance structure to the internal light extraction of the OLED lighting panel. This is because the micro-resonance may cause spectrum narrowing. As the strong cavity is used, the spectrum may be narrower. Thus, only light of very narrow wavelength region may be strongly emitted, and emitting efficiency of light of wavelengths except the corresponding wavelength region may be reduced.

If the micro-resonance structure is used in the OLED lighting panel using the white organic electroluminescent device, the color of light emitted from the panel may deviate from a white range and the light extraction efficiency of the light of wavelengths except a specific wavelength may be reduced. It is preferable to apply the micro-resonance effect to a display panel emitting lights of RGB colors individually or an OLED panel emitting light of a single color.

The photonic crystal of the internal light extraction may include two materials having dielectric constants different from each other which are arranged on a nanometer-scale with a regular period. The photonic crystal may allow light to be transmitted or forbidden depending on the wavelength of the light. Thus, the photonic crystal may transmit the light of a specific wavelength. Here, the forbidden wavelength region is defined as a photonic band gap. It is possible to manufacture an optic device using the above phenomenon and capable of changing a light path without loss. The photonic crystal may be categorized as one of a one-dimensional photonic crystal called ‘Bragg grating’, a two-dimensional photonic crystal including protrusions of an embossing structure arranged with a regular period on a plane, and a three-dimensional photonic crystal. The photonic crystal may use light diffraction. In other words, the photonic crystal may be provided on a planar waveguide formed in the organic electroluminescent device for preventing light from being transmitted in a planar direction, thereby forming a forbidden band. Thus, the light emitted from the organic light emitting layer may not form a guided mode and may be outputted outside. The two-dimensional photonic crystal using this phenomenon may be formed in the organic electroluminescent device to increase the light extraction efficiency. The photonic crystal may be applied to a single color light OLED. However, if the photonic crystal is applied to the OLED lighting panel using the white OLED, only the light extraction efficiency of light having a specific wavelength may increase.

The internal light scattering layer of the internal light extraction may not cause color variation according to a view angle and may maintain Lambertian distribution like the external light scattering layer. Thus, the brightness of the panel using the internal light scattering layer may be uniform. For forming the internal light scattering layer, materials having refractive indexes different from each other may be mixed and then the mixed materials may be coated on a glass substrate. Thus, the internal light scattering layer may be relatively easily formed. If the internal light scattering layer is applied, the light extraction efficiency may increase, the color variation according to the view angle may decrease, and the light distribution of the organic electroluminescent device may be close to the Lambertian distribution. The number of scattering centers should increase for increasing the light scattering effect. However, if the number of scattering centers is too increased, a back scattering effect may increase. Thus, the scattering light may be absorbed in the organic light emitting layer again. Thus, the scattering degree and the internal absorption should be optimized to increase the light extraction efficiency if the light is not absorbed in the light scattering layer. However, if the light is absorbed in the light scattering layer, the increase amount of the light efficiency by the light extraction effect may be reduced by the absorption of the light scattering layer. If an absorbance in the light scattering layer is 0.1, a light efficiency drop caused by the absorption may be greater than the light extraction effect. Thus, for using the internal light scattering layer as the internal light extraction structure, the internal light scattering layer may be thin in order that the absorbance of the light scattering is less than 0.1.

The nano embossing structure of the internal light extraction may be a light extraction structure using advantages of the photonic crystal and the light scattering layer. As described above, the photonic crystal structure may be used n only the wavelength band of the specific light, so that it may not be used in the white OLED. The light scattering layer may cause the internal absorption to decrease the light extraction effect. Similarly to the photonic crystal, the nano embossing structure may use an embossing structure having a size of several hundreds nm as the internal light extraction structure. However, protrusions of the nano embossing structure may be irregularly arranged. The nano embossing structure having this arrangement may partially cause the diffraction effect and function as a single-layered light scattering layer. Thus, the nano embossing structure may substantially remove dependence on the wavelength, the color variation caused by the view angle, distortion of the light distribution. Additionally, the self-absorption of the nano embossing structure may be disregarded.

FIG. 8 is a schematic view illustrating an organic electroluminescent device according to some embodiments of the inventive concept.

An organic electroluminescent device illustrated in FIG. 8 may include a first light emitting part 230 emitting light of a first wavelength, and a capping layer 250 reflecting the light of the first wavelength and transmitting light of a second wavelength. The first light emitting part 230 may include a transparent first electrode 231, a first organic light emitting layer 233, and a transparent second electrode 235 which are stacked.

All of the first and second electrodes 231 and 235 are transparent, so that a transparent organic electroluminescent device may be constituted. The transparent organic electroluminescent device may emit the light of the first wavelength in front thereof and transmit the light of the second wavelength inputted from the outside thereof.

The capping layer 250 may be stacked on the first light emitting part 230. If the first electrode 231, the first organic light emitting layer 233, and the second electrode 235 of the first light emitting part 230 are sequentially stacked, the capping layer 250 may be disposed under the first electrode 231 and/or on the second electrode 235. Alternatively, the capping layer 250 may be disposed in the inside of each of the first and second electrodes 231 and 235. In other words, each of the first and second electrodes 231 and 235 may consist of two layers, and the capping layer 250 may be disposed between the two layers.

As illustrated in FIG. 8, For example, the first light emitting part 230 may be disposed on a substrate 210, and the capping layer 250 may be disposed on a surface (an outer surface) of the second electrode 235 which is opposite to a stacked surface of the second electrode 235 adjacent to the first organic light emitting layer 233. In more detail, the substrate 210, the first electrode 231, the first organic light emitting layer 233, the second electrode 235, and the capping layer 250 may be sequentially stacked in the organic electroluminescent device illustrated in FIG. 8. Here, an additional layer performing an additional function may be disposed the layers. The first electrode 231 may be a transparent anode, and the second electrode 235 may be a transparent cathode. In other embodiments, the first electrode 231 may be the transparent cathode, and the second electrode 235 may be the transparent anode. The substrate 210 may be a transparent substrate formed of a glass or a synthetic resin material. The cathode may be formed of a metal, so that the cathode may be very thin for obtain the transparent property.

The capping layer 250 reflects the light of the first wavelength which is emitted from the first light emitting part 230, more particularly, from the first organic light emitting layer 233. Additionally, the capping layer 250 transmits the light of the second wavelength different from the first wavelength.

Thus, the light of the first wavelength generated from the first light emitting part 230 is reflected by the capping layer 250 stacked on the first light emitting part 230 and then is irradiated in one of both plane-directions of the first light emitting part 230. For example, if the capping layer 250 is disposed on the outer surface of the second electrode 235, the light of the first wave length generated from the first organic light emitting layer 233 is not irradiated toward the second electrode 235.

Additionally, the capping layer 20 transmits the light of the second wavelength. The light of the second wavelength is different from the light of the first wavelength. The light of the second wavelength is inputted to the first light emitting part 230 from the outside of the organic electroluminescent device. In other words, the light of the second wavelength is not generated from the first light emitting part 230. By the way, each of the first and second wavelengths according to the inventive concept may mean one wavelength or a plurality of wavelengths. As illustrated in FIG. 8, if the light of the second wavelength is inputted to the second electrode 235, the light of the second wavelength is irradiated toward the first electrode 231. At this time, the irradiating direction the light of the second wavelength is the same as that of the light of the first wavelength.

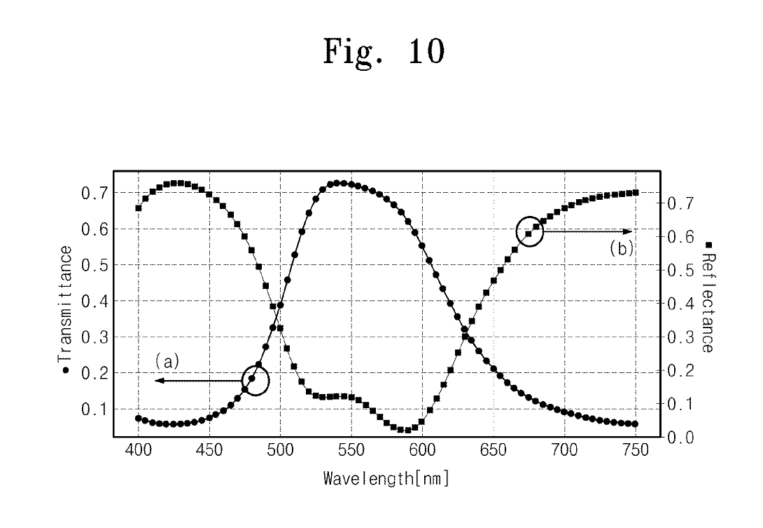

According to the transparent organic electroluminescent device described above, the light self-emitted from the organic electroluminescent device may be irradiated in one direction by the capping layer 250, so that the organic electroluminescent device may be applied to a lighting system irradiating light toward one surface thereof to increase the light efficiency. Additionally, if the light of the second wavelength is inputted from the outside of the organic electroluminescent device, the light of the second wavelength is reliably combined with the light of the first wavelength to change a color. The capping layer 250 may include a dielectric mirror having stacked dielectric materials of which refractive indexes are different from each other. The dielectric materials having the different refractive indexes are stacked, so that an interface of the stacked dielectric materials may function as a mirror by difference between the refractive indexes of the stacked dielectric materials. Light transmittance(a) and light reflectance(b) of the capping layer 250 according to a wavelength are shown in FIG. 10. As illustrated in FIG. 10, the light transmittance(a) and the light reflectance(b) may be changed depending on a wavelength. The light transmittance(a) and the light reflectance(b) may be optimized using the features illustrated in FIG. 10.

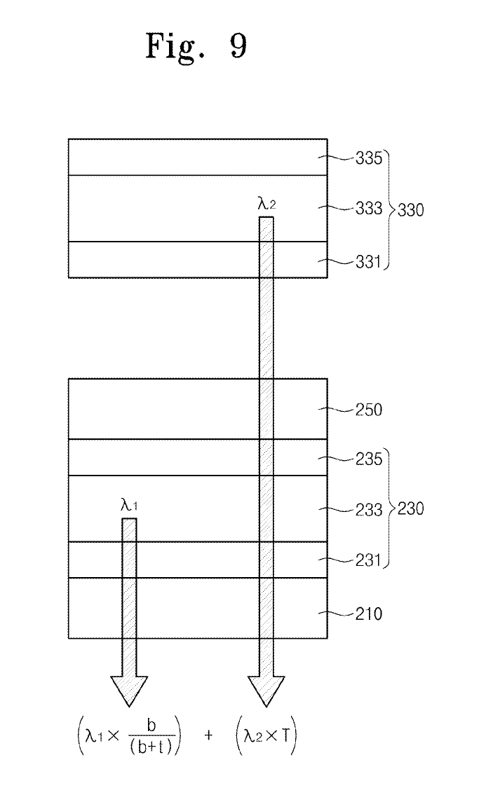

FIG. 9 is a schematic view illustrating an organic electroluminescent device according to other embodiments of the inventive concept.

An organic electroluminescent device may include a first light emitting part 230, a second light emitting part 330, and a capping layer 250 disposed between the first light emitting part 230 and the second light emitting part 330. The first light emitting part 230 may include a transparent first electrode 231, a first organic light emitting layer 233, and a transparent second electrode 235 which are stacked. The first light emitting part 230 emits light of a first wavelength. The second light emitting part 330 may include a transparent third electrode 331, a second organic light emitting layer 333, and a reflective fourth electrode 335 which are stacked. The second light emitting part 330 emits light of a second wavelength. The capping layer 250 reflects the light of the first wavelength and transmits the light of the second wavelength.

In more detail, the first light emitting part 230 corresponding to a transparent OLED and the second light emitting part 330 corresponding to a reflective OLED are stacked to constitute a combined organic electroluminescent device. The capping layer 250 is disposed between the first organic light emitting layer 233 and the second organic light emitting layer 333. In FIG. 9, the capping layer 250 is stacked on the second electrode 235 of the first light emitting part 230. At this time, the capping layer 250 may further function as a passivation layer protecting the first light emitting part 230.

The capping layer 250 has a high reflectance with respect to the light of the first wavelength generated from the first light emitting part 230 and a high transmittance with respect to the light of the second wavelength generated from the second light emitting part 330.

Wherein λ₁ is the intensity of the light of the first wavelength, λ₂ is the intensity of the light of the second wavelength, T is the transmittance of the capping layer 250 with respect to the light of the second wavelength, t is the intensity of the light of the first wavelength irradiated from the first light emitting part 230 to the second electrode 235, and b is the intensity of the light of the first wavelength irradiated from the first light emitting part 230 to the first electrode 231, the intensity of total light irradiated to the first electrode 231 may be equal the sum of λ₁×b/(b+t) and λ₂×T. The intensity of the light of the first wavelength irradiated to the second light emitting part 330 is λ₁×t/(b+t). For improving the efficiency of the light irradiated to the first electrode 231, the capping layer 250 has the high transmittance with respect to the light of the second wavelength. Additionally, for increasing b/(b+t), the capping layer 250 has the high reflectance with respect to the light of the first wavelength.

As a result, the light of the first wavelength may not be transmitted to the second light emitting part 330 but may be irradiated to the first electrode 231. The light of the second wavelength may also be irradiated to the first electrode 231 by the reflective fourth electrode 335. Since the light of the first wavelength may not be irradiated to the second light emitting part 330, the light efficiency of the light of the first wavelength may be improved. Additionally, the light of the first wavelength and the light of the second wavelength may be combined with each other in the first light emitting part 230 to easily obtain light of a desired color.

As described above, an ideal case is described for explaining the functions of the capping layer 250. Actually, it is difficult to find a material having the reflectance of 100% with respect to the first wavelength and the transmittance of 100% with respect to the second wavelength.

In an experiment, it was confirmed that the capping layer 250 having the reflectance of 40% or more with respect to the first wavelength and the transmittance of 60% or more with respect to the second wavelength improved the light efficiency of the organic electroluminescent device. Thus, the capping layer 250 according to the inventive concept has the reflectance of 40% or more with respect to the first wavelength and the transmittance of 60% or more with respect to the second wavelength.

Meanwhile, a micro-resonator micro-resonating the light of the second wavelength may be disposed between the first light emitting part 230 and the second light emitting part 330 to improve the light extraction of the light of the second wavelength. The micro-resonator may require a Bragg mirror layer or a metal mirror layer reflecting the light generated from the second organic light emitting layer 333. Here, at least the fourth electrode 335 of the second light emitting part 330 may function as the Bragg mirror layer or the metal mirror layer of the micro-resonator.

If powers applied to the first to fourth electrodes 231, 235, 331, and 335 are changed, a color of the light outputted from the first electrode 231 is varied. For example, if the first light emitting part 230 emits light of a red color and the second light emitting part 330 emits light of a green color, the color of the light outputted from the first electrode 231 is a synthetic color of the red and green. Here, if the power applied to the first and second electrodes 231 and 235 is controlled to control the intensity of the red color or the power applied to the third and fourth electrodes 331 and 335 is controlled to control the intensity of the green color, the final synthetic color may be varied. At this time, the light generated from the first light emitting part 230 may be mainly irradiated to the first electrode 231 by the capping layer 250. Thus, the light irradiated to the second light emitting part 330 may not influence the light generated from the second light emitting part 330. As a result, according to the organic electroluminescent device of the inventive concept, the color variation may be easily and reliably performed.

As described above, the organic electroluminescent device according to the inventive concept includes the capping layer reflecting the light of the first wavelength generated from the transparent light emitting part and transmitting the light of the second wavelength different from the first wavelength. Thus, the lights of the first and second wavelengths may be irradiated in high efficiency.

As a result, the organic electroluminescent device may provide more high light efficiency and effectively combine the lights of the first and second wavelengths from each other to provide the color variation function with reliability.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. An organic electroluminescent device comprising:
a first light emitting part including a transparent first electrode, a first organic light emitting layer, and a transparent second electrode which are stacked, the first light emitting part emitting light of a first wavelength; and
a capping layer stacked on the first light emitting part, the capping layer reflecting the light of the first wavelength and transmitting light of a second wavelength.

2. The organic electroluminescent device of claim 1, wherein the capping layer is stacked on the second electrode.

3. The organic electroluminescent device of claim 2, wherein the first electrode is an anode and the second electrode is a cathode.

4. The organic electroluminescent device of claim 1, wherein the first electrode, the first organic light emitting layer, the second electrode, and the capping layer are sequentially stacked on a transparent substrate.

5. The organic electroluminescent device of claim 1, wherein the capping layer reflects 40% or more of the light of the first wavelength and transmits 60% or more of the light of the second wavelength.

6. The organic electroluminescent device of claim 1, wherein the capping layer includes a dielectric mirror formed of stacked dielectric materials of which refractive indexes are different from each other.

7. An organic electroluminescent device comprising:
a first light emitting part including a transparent first electrode, a first organic light emitting layer, and a transparent second electrode which are stacked, the first light emitting part emitting light of a first wavelength;
a second light emitting parting including a transparent third electrode, a second organic light emitting layer, and a reflective fourth electrode which are stacked, the second light emitting part emitting light of a second wavelength; and
a capping layer disposed between the first organic light emitting layer and the second organic light emitting layer, the capping layer reflecting the light of the first wavelength and transmitting the light of the second wavelength.

8. The organic electroluminescent device of claim 7, wherein the capping layer is stacked on the second electrode.

9. The organic electroluminescent device of claim 8, wherein the first electrode is an anode and the second electrode is a cathode.

10. The organic electroluminescent device of claim 7, wherein the first electrode, the first organic light emitting layer, the second electrode, and the capping layer are sequentially stacked on a transparent substrate.

11. The organic electroluminescent device of claim 7, wherein the capping layer reflects 40% or more of the light of the first wavelength and transmits 60% or more of the light of the second wavelength.

12. The organic electroluminescent device of claim 7, wherein the capping layer includes a dielectric mirror formed of stacked dielectric materials of which refractive indexes are different from each other.

13. The organic electroluminescent device of claim 7, further comprising:
a micro-resonator of the second wavelength disposed between the first light emitting part and the second light emitting part.

14. The organic electroluminescent device of claim 7, wherein powers applied to the first to fourth electrodes are changed to vary a color of light outputted to the first electrode.
